(19) United States
(12) Patent Application Publication
(10) Pub. No.: US 2023/0176487 A1
(43) Pub. Date: Jun. 8, 2023

(54) SUBSTRATE SUPPORT SYSTEM, LITHOGRAPHIC APPARATUS AND METHOD OF EXPOSING A SUBSTRATE

(71) Applicant: ASML NETHERLANDS B.V., Veldhoven (NL)

(72) Inventors: Rogier Sebastiaan GILIJAMSE, Veldhoven (NL); Johan Gertrudis Cornelis KUNNEN, Weert (NL); Marco Adrianus Peter VAN DEN HEUVEL, Waalre (NL); Boogyeong Zoo, Wuxi (KR)

(73) Assignee: ASML NETHERLANDS B.V., Veldhoven (NL)

(21) Appl. No.: 17/922,580

(22) PCT Filed: May 3, 2021
(86) PCT No.: PCT/EP2021/061503

§ 371 Date: Oct. 31, 2022

(30) Foreign Application Priority Data
Feb. 19, 2001 (CN) PCT/CN2021/076817
May 15, 2020 (EP) 20174973.6

(51) Int. Cl. G03F 7/20

(52) U.S. Cl. CPC G03F 7/70533; G03F 7/7085; G03F 7/70783

(57) ABSTRACT

A substrate support system is provided that includes: a support part configured to support a bottom surface of a substrate on a support plane; a moveable part moveable between a retracted position, in which a top end of the moveable part is below the support plane, and an extended position, in which the top end of the moveable part is above the support plane, such that the top end supports the bottom surface of the substrate above the support plane in the extended position; and a measurement system configured to measure a time taken for the moveable part to move from the retracted position to the extended position, to compare the measured time with a reference time, and to generate a signal when the measured time deviates from the reference time by more than a predetermined amount.

### CROSS-REFERENCE TO RELATED APPLICATIONS

This application claims priority of EP application 20174973.6 which was filed on May 15, 2020 and PCT application PCT/CN2021/076817 which was filed on Feb. 19, 2021 and which are incorporated herein in its entirety by reference.

### FIELD

The present invention relates to a substrate support system, a lithographic apparatus and a method of exposing a substrate. It is particularly, but not exclusively, concerned with systems, apparatus and methods which measure the unloading time of a substrate from a support and compare it to a reference value.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as “Moore's law”. To keep up with Moore's law the semiconductor industry is seeking technologies that make it possible to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm.

Immersion techniques have been introduced into lithographic systems to enable improved resolution of smaller features. In an immersion lithographic apparatus, a liquid layer of immersion liquid having a relatively high refractive index is interposed in a space between a projection system of the apparatus (through which the patterned beam is projected towards the substrate) and the substrate. The immersion liquid covers at last the part of the substrate under a final element of the projection system. Thus, at least the portion of the substrate undergoing exposure is immersed in the liquid. The effect of the immersion liquid is to enable imaging of smaller features since the exposure radiation will have a shorter wavelength in the immersion liquid than gas. (The effect of the liquid may also be regarded as increasing the effective numerical aperture (NA) of the system and also increasing the depth of focus.)

In commercial immersion lithography, the immersion liquid is water. Typically the water is distilled water of high purity, such as Ultra-Pure Water (UPW) which is commonly used in semiconductor fabrication plants. In an immersion system, the UPW is often purified and it may undergo additional treatment steps before supply to the space as immersion liquid. Other liquids with a high refractive index can be used besides water can be used as the immersion liquid, for example: a hydrocarbon, such as a fluorohydrocarbon; and/or an aqueous solution. Further, other fluids besides liquid have been envisaged for use in immersion lithography. In this specification, reference will be made in the description to localized immersion in which the immersion liquid is confined, in use, to the space between the final element and a surface facing the final element. The facing surface is a surface of substrate or a surface of a support table (or a substrate support) that is co-planar with the surface of the substrate. (Please note that reference in the following text to surface of the substrate also refers in addition or in the alternative to a surface of the substrate support, unless expressly stated otherwise; and vice versa). A fluid handling structure present between the projection system and the stage is used to confine the immersion to the space. The space filled by immersion liquid is smaller in plan than the top surface of the substrate and the space remains substantially stationary relative to the projection system while the substrate and substrate stage move underneath.

In lithographic systems the substrates are clamped onto a substrate table. Seals are present near the edge of the substrate to ensure that an underpressure can be created to keep the substrate in place and the wafer “clamped” to the substrate table. The substrate rests on many projections or burls on the substrate table. During loading of the substrates onto the substrate table the friction of burls near the substrate edge has a large effect on any deformation of the substrate. This is particularly important for so-called “umbrella” substrates which first make contact with burls near the edge, e.g., outer burls. In immersion systems, the area near the outer burls on the substrate table is generally wet and remains wet when the substrates are loaded.

A change in the friction properties of the burls may lead to uncorrectable deformation of the substrate during the loading of the substrate onto substrate table.

An object of the present invention is to provide systems and methods which are able to identify substrates which may have experienced significant deformation during clamping, preferably without requiring inspection of the substrate itself.

### SUMMARY

A first aspect of the present invention provides a substrate support system, comprising: a support part, the support part configured to support a bottom surface of a substrate on a support plane; a moveable part, the moveable part moveable between a retracted position, in which a top end of the moveable part is below the support plane, and an extended position, in which the top end of the moveable part is above the support plane, such that the top end contacts the bottom surface of a substrate supported by the support part when moving between the retracted and extended positions and supports the bottom surface of the substrate above the support plane in the extended position; and a measurement system configured to measure a time taken for the moveable part to move from the retracted position to the extended position, to compare the measured time with a reference time, and to generate a signal when the measured time deviates from the reference time by more than a predetermined amount.

A second aspect of the present invention provides a stage positioning system comprising: a substrate support system arranged to support a substrate; a clamping system arranged to hold the substrate on the substrate support whilst the substrate is being exposed to radiation; a processor; and either: a) a sensor arranged to measure a time taken for a substrate to be removed from the substrate support, wherein the processor is arranged to compare the time measured by the sensor to a reference time, and to generate a signal when the measured time deviates from the reference time by more than a predetermined amount, or b) a sensor arranged to measure a change in a pressure used by the clamping system to clamp the substrate to the substrate support, wherein the processor is arranged to compare the measured pressure change to a reference, and to generate a signal based on the comparison.

A third aspect of the present invention provides a method of exposing a substrate in a lithographic process, the method including the steps of: clamping the substrate to a support structure; exposing the clamped substrate to radiation; and removing the substrate from the support structure, wherein the method further includes the steps of either: a) measuring a time taken to remove the substrate from the support structure; comparing the measured time to a predetermined reference time; and if the measured time deviates from the reference time by more than a predetermined amount, generating a signal, or b) measuring a change in a pressure used to clamp the substrate to the support structure during the step of clamping; comparing the measured pressure change to a predetermined reference; and, based on the comparison, generating a signal.

Further aspects of the present invention provide a computer program comprising computer readable instructions which, when run on suitable computer apparatus, cause the computer apparatus to perform the method the above aspect and a computer readable medium having such a computer program stored thereon.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 depicts an outer portion of a substrate table of a lithographic apparatus;

FIG. 3 shows, schematically, the interaction between a substrate and a substrate table;

FIG. 4 shows a comparison between the outer portion of a substrate table which is dry and one which is wet;

FIG. 5a shows a clamping fingerprint for a substrate which has been unloaded from a wet substrate table, while FIG. 5b shows a clamping fingerprint for a substrate which has been unloaded from a dry substrate table;

FIG. 6 shows the substrate unload times for substrates from substrate tables with different degrees of wetness;

FIG. 7 shows the movement of e-pins over time during the unloading of a substrate from a substrate table;

FIG. 8 shows the changes in the observed positions of markers from their expected positions for three lots of substrates as a function of their location within a lot;

FIG. 9 shows the overall changes in the observed positions of markers from their expected positions for a set of lots of substrates as a function of their location within the lot; and

FIG. 10 shows the pre-clamp pressure profiles over time for a plurality of substrates.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

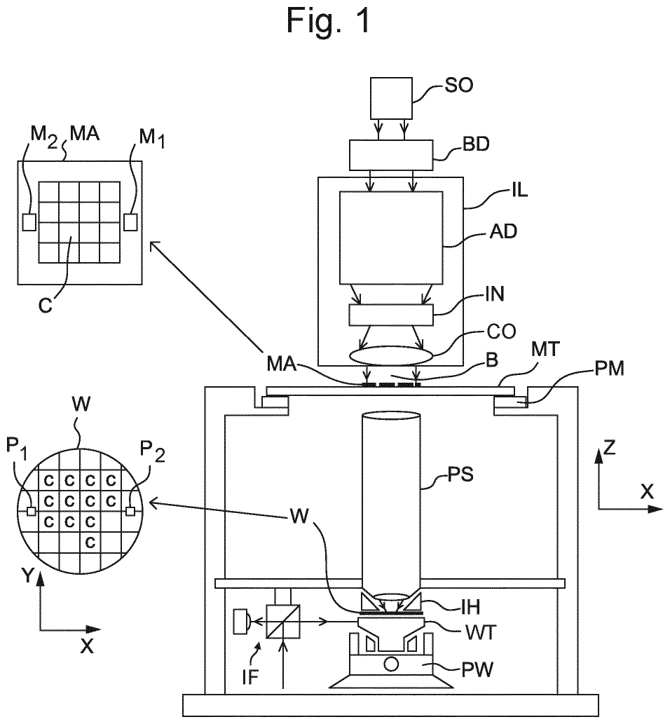

FIG. 1 schematically depicts a lithographic apparatus. The apparatus comprises:

a. optionally, an illumination system (illuminator) IL configured to condition a radiation beam B (e.g. UV radiation or DUV radiation);
b. a support structure (e.g. a mask table) MT constructed to support a patterning device (e.g. a mask) MA and connected to a first positioner PM configured to accurately position the patterning device MA in accordance with certain parameters;
c. a support table, e.g. a sensor table to support one or more sensors or a substrate table WT constructed to hold a substrate (e.g. a resist-coated substrate) W, connected to a second positioner PW configured to accurately position the surface of the table, for example of a substrate W, in accordance with certain parameters; and
d. a projection system (e.g. a refractive projection lens system) PS configured to project a pattern imparted to the radiation beam B by patterning device MA onto a target portion C (e.g. comprising one or more dies) of the substrate W.

In operation, the illumination system IL receives a radiation beam from a source SO or radiation, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid. Any use of the term “projection lens” herein may be considered as synonymous with the more general term “projection system”.

The lithographic apparatus may be of a type wherein at least a portion of the substrate W may be covered by an immersion liquid having a relatively high refractive index, e.g., water, so as to fill an immersion space between the projection system PS and the substrate W—which is also referred to as immersion lithography. More information on immersion techniques is given in U.S. Pat. No. 6,952,253, which is incorporated herein by reference.

The lithographic apparatus may be of a type having two or more substrate tables WT (also named “dual stage”). In such “multiple stage” machine, the substrate tables WT may be used in parallel, and/or steps in preparation of a subsequent exposure of the substrate W may be carried out on the substrate W located on one of the substrate table WT while another substrate W on the other substrate table WT is being used for exposing a pattern on the other substrate W.

In addition to the substrate table WT, the lithographic apparatus may comprise a measurement stage (not depicted in FIG. 1). The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate table WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF (e.g. an interferometric device, linear encoder, 2-D encoder or capacitive sensor), the substrate table WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

In this specification, a Cartesian coordinate system is used. The Cartesian coordinate system has three axis, i.e., an x-axis, a y-axis and a z-axis. Each of the three axis is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

A localized liquid supply system or fluid handling system is provided between the projection system PS and the substrate W. The liquid supply system is provided with a fluid handling structure IH (or liquid confinement structure), which extends along at least a part of a boundary of the space between the final element of the projection system PS and the substrate table WT or substrate W. The fluid handling structure IH is substantially stationary relative to the projection system PS in the XY plane though there may be some relative movement in the Z direction (in the direction of the optical axis). In an example, a seal is formed between the fluid handling structure IH and the surface of the substrate W and may be a contactless seal such as a gas seal (such a system with a gas seal is disclosed in EP1,420,298) or liquid seal.

The fluid handling structure IH at least partly confines the immersion liquid in the space between the final element of the projection system PS and the substrate W. The space is at least partly formed by the fluid handling structure IH positioned below and surrounding the final element of the projection system PS. Immersion liquid is brought into the space below the projection system PS and within the fluid handling structure IH by one of liquid openings. The immersion liquid may be removed by another of liquid openings.

The immersion liquid may be confined in the space by a contactless seal such as a gas seal formed by a gas which, during use, is formed between the bottom of the fluid handling structure IH and the surface of the substrate W. The gas in the gas seal is provided under pressure via inlet to the gap between the fluid handling structure IH and substrate W. The gas is extracted via outlet. The overpressure on the gas inlet, vacuum level on the outlet and geometry of the gap are arranged so that there is a high-velocity gas flow inwardly that confines the immersion liquid. Such a system is disclosed in US 2004/0207824, which is hereby incorporated by reference in its entirety. In an example, the fluid handling structure IH does not have the gas seal.

Another example of a liquid supply system is disclosed in US 2010/0045949 A1, which is hereby incorporated by reference in its entirety.

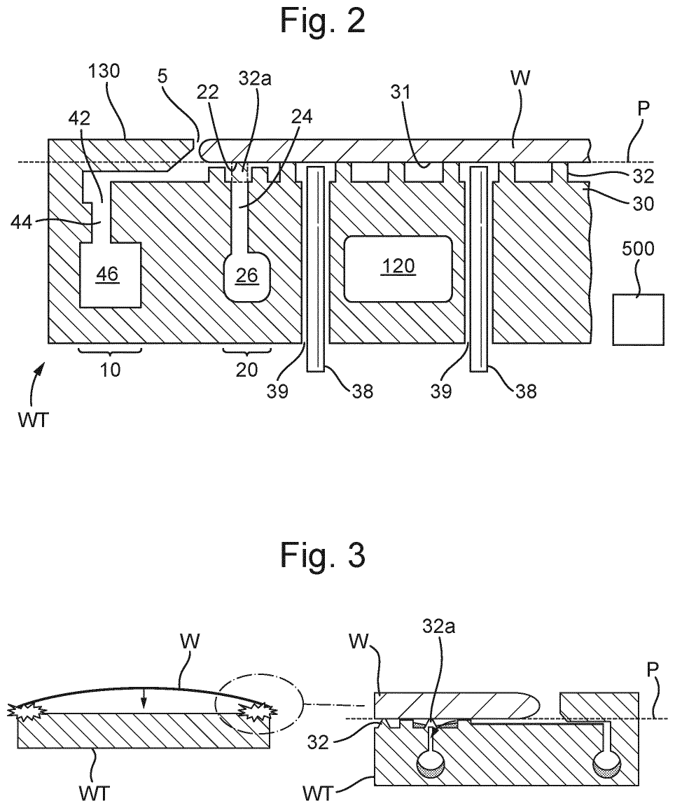

FIG. 2 illustrates part of a lithographic apparatus according to an embodiment of the present invention. The arrangement illustrated in FIG. 2 and described below may be applied to the lithographic apparatus described above and illustrated in FIG. 1. FIG. 2 is a cross-section through a substrate table WT and a substrate W. A gap 5 exists between an edge of the substrate W and an edge of the substrate table WT. When the edge of the substrate W is being imaged or at other times such as when the substrate W first moves under the projection system PS (as described above), the immersion space filled with liquid by the liquid confinement structure IH (for example) will pass at least partly over the gap 5 between the edge of the substrate W and the edge of the substrate table WT. This can result in liquid from the immersion space entering the gap 5.

The substrate W is held by a support body 30 (e.g. a pimple or burl table) comprising one or more projections 32 (i.e., burls). The support body 30 is an example of an object holder. Another example of an object holder is a mask holder. An under-pressure applied between the substrate W and the substrate table WT helps ensure that the substrate W is held firmly in place. However, if immersion liquid gets between the substrate W and the support body 30 this can lead to difficulties, particularly when unloading the substrate W.

In order to deal with the immersion liquid entering that gap 5 at least one drain 10, 20 is provided at the edge of the substrate W to remove immersion liquid which enters the gap 5. In the embodiment of FIG. 2 two drains 10, 20 are illustrated though there may only be one drain or there could be more than two drains. In an embodiment, each of the drains 10, 20 is annular so that the whole periphery of the substrate W is surrounded.

A primary function of the first drain 10 (which is radially outward of the edge of the substrate W/support body 30) is to help prevent bubbles of gas from entering the immersion space where the liquid of the liquid confinement structure IH is present. Such bubbles may deleteriously affect the imaging of the substrate W. The first drain 10 is present to help avoid gas in the gap 5 escaping into the immersion space in the liquid confinement structure IH. If gas does escape into the immersion space, this can lead to a bubble which floats within the immersion space. Such a bubble, if in the path of the projection beam, may lead to an imaging error. The first drain 10 is configured to remove gas from the gap 5 between the edge of the substrate W and the edge of the recess in the substrate table WT in which the substrate W is placed. The edge of the recess in the substrate table WT may be defined by a cover ring 130 which is optionally separate from the support body 30 of the substrate table WT. The cover ring 130 may be shaped, in plan, as a ring and surrounds the outer edge of the substrate W. The first drain 10 extracts mostly gas and only a small amount of immersion liquid.

The second drain 20 (which is radially inward of the edge of the substrate W/support body 30) is provided to help prevent liquid which finds its way from the gap 5 to a space underneath the substrate W from preventing efficient release of the substrate W from the substrate table WT after imaging. The provision of the second drain 20 reduces or eliminates any problems which may occur due to liquid finding its way underneath the substrate W.

As depicted in FIG. 2, in an embodiment the lithographic apparatus comprises a channel 46 for the passage therethrough of a two phase flow. The channel 46 is formed within a block. The first and second drains 10, 20 are each provided with an opening 42, 22 and a channel 46, 26. The channel 46, 26 is in fluid communication with the respective opening 42, 22 through a passageway 44, 24. One or more outer projections 32a may be provided in the same region as the second drain 20. The opening 22 of the second drain 20 may be blocked in the location of the outer projections 32a, or the opening 22 may comprise a plurality of individual openings which alternate with outer projections 32a, or are arranged in some other repeating or non-repeating pattern.

As depicted in FIG. 2, the cover ring 130 has an upper surface. The upper surface extends circumferentially around the substrate W on the support body 30. In use of the lithographic apparatus, the substrate table WT moves relative to the liquid confinement structure IH. During this relative movement, the liquid confinement structure IH may be located at a position across the gap 5 between the cover ring 130 and the substrate W. In an embodiment the relative movement is caused by the substrate table WT moving under the liquid confinement structure IH. In an alternative embodiment the relative movement is caused by the liquid confinement structure IH moving over the substrate table WT. In a further alternative embodiment the relative movement is provided by movement of both the substrate table WT under the liquid confinement structure IH and movement of the liquid confinement structure IH over the substrate WT. In the following description, movements of the liquid confinement structure IH will be used to mean the relative movement of the substrate table WT relative to the liquid confinement structure IH.

A plurality of pins (or e-pins) 38 project through holes 39 in the substrate table WT. The e-pins 38 are shown in FIG. 2 in a retracted position in which the upper surface of the e-pin 38 is below a support plane P which is defined by end surfaces of the projections 32 and outer projections 32a and coincides with the bottom surface of the substrate W when resting on the projections 32 and outer projections 32a. The e-pins 38 are used to unload the substrate W from the substrate table WT when the exposure to patterning radiation has been completed. To unload the substrate W, the e-pins 38 are moved upwards to an extended position, so that the upper surface of the e-pins 38 first contacts the bottom surface of the substrate W and then lifts the substrate W off the projections 32 and outer projections 32a. Once the substrate W has been lifted off the projections 32 and outer projections 32a, the substrate W can be picked up and re-located by other mechanisms within the lithographic apparatus.

Substrates W can be subject to deformation as a result of their handling in the lithographic apparatus. Such deformation is generally undesirable, as it can cause problems with the subsequent alignment of the substrate W and the patterning being applied. Whilst some deformation can be measured and adjusted for in subsequent steps of the lithographic process, it may not be possible to adjust for excessive and/or unusual deformation which can thus result in inaccuracies in the subsequent process. It is thus desirable to identify substrates W which have suffered, or are likely to have suffered, excessive and/or unusual deformations as early as possible in the lithographic process after such deformations have or may have resulted.

Deformations resulting from various actions within the lithographic process are sometimes referred to as “fingerprints”. For example, deformation resulting from the loading, clamping and unloading process of the substrate W by a stage positioning system, comprising a substrate support system including the substrate table WT, and a clamping system, may be referred to as the “substrate clamping fingerprint”. During the loading of substrates W onto the substrate table WT, friction of the projections 32 near the edge of the substrate W determines to a significant extent the substrate clamping fingerprint. In particular, any sudden change in the friction properties of the projections 32, and in particular those projections around the edge of the substrate table WT, can result in uncorrectable substrate clamping fingerprints.

This may be especially important for so-called “umbrella substrates” which have a domed structure which is generally concave with respect to the substrate table WT and thus first make contact with the projections 32 near the edge of the substrate table WT, e.g., the outer projections 32a, as shown on the left-hand side of FIG. 3. The right-hand side of FIG. 3 shows the outer region of a substrate W supported on a support plane P by projections 32, outer projections 32a on the substrate table WT.

In an immersion system, the area near the projections 32 towards the edge of the substrate table WT (and the substrate W when placed on the substrate table WT) is wet and remains wet when the substrates W are loaded. Liquid is slowly removed through extraction openings 22.

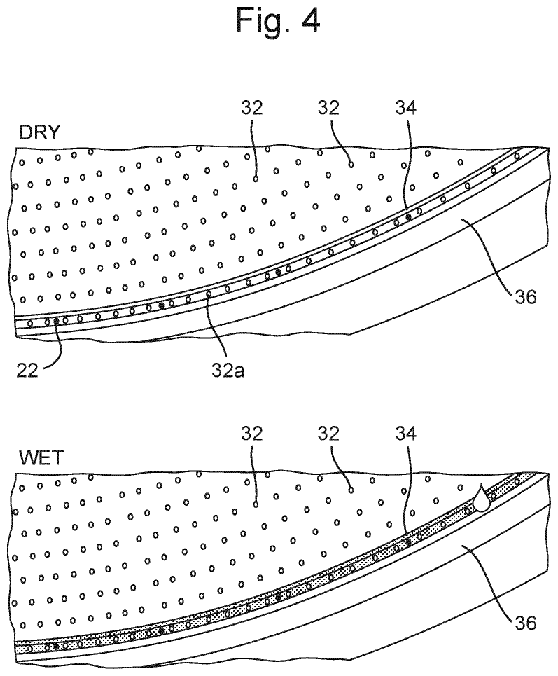

The present inventors have noticed that the presence of different amounts of liquid between the inner, i.e., first, and outer, i.e. second, seal can result in significant changes in the friction properties of the projections, e.g., second projections, in this region. This is shown in the photographs of a substrate table in FIG. 4, in which the upper picture shows a dry substrate table WT in the region of the outer projections 32a, i.e., second projections and extraction openings 22 which are formed between the inner seal 34 and the outer seal 36. The lower picture in FIG. 4 shows the same region when the substrate table WT is wet, which shows up due to the darker colouring of this region.

The present inventors have also observed that when the area in the region of the outer projections 32a dries, for example due to a delay in the operation of the system, the friction between the substrate table WT and the substrate W changes. This results in a substrate W which is loaded onto a dry substrate table WT (for example directly after the delay) may show a large clamping fingerprint.

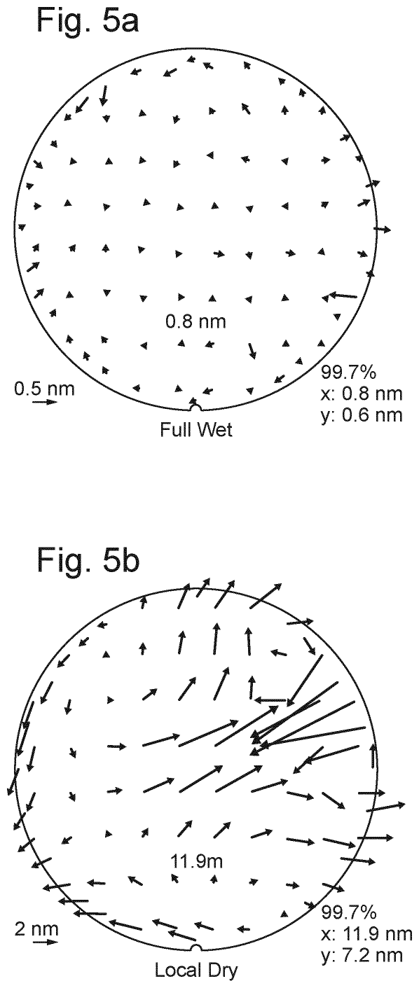

FIG. 5 shows a), in the upper figure, a typical clamping fingerprint for a substrate W which has been loaded during normal operation and in which the edge region of the substrate table WT has remained fully wet and b), in the lower figure, the fingerprint for the same substrate W after it has been loaded onto a substrate table WT in which there has been deliberate local drying of the substrate table WT particularly in the region contacted by the portion of the substrate W seen at the upper right of FIG. 5b.

In the clamping fingerprints, the arrows show the position of alignment markers relative to their expected, non-deformed position. The origin of each arrow is the expected position of the alignment marker, while the length of each arrow depicts the extent of the movement of the alignment marker from the expected position.

It can be seen that the locally dry substrate experiences much greater deformation and across a substantial portion of the substrate W, with a mean three-sigma of all the changes in the observed positions of the markers from their expected positions of 11.9 nm. In contrast, the fully wet fingerprint shows only minimal and localised deformation with a mean three-sigma change of 0.8 nm.

As a result, substrates W which have experienced locally (or completely) dry contact with the substrate table WT are likely to have deformed significantly and may need to be rejected from the lithographic process. If such substrates W can be identified and/or rejected timely after experiencing the deformation, in particular before they are subject to further processing, then savings can be made in the overall lithographic process.

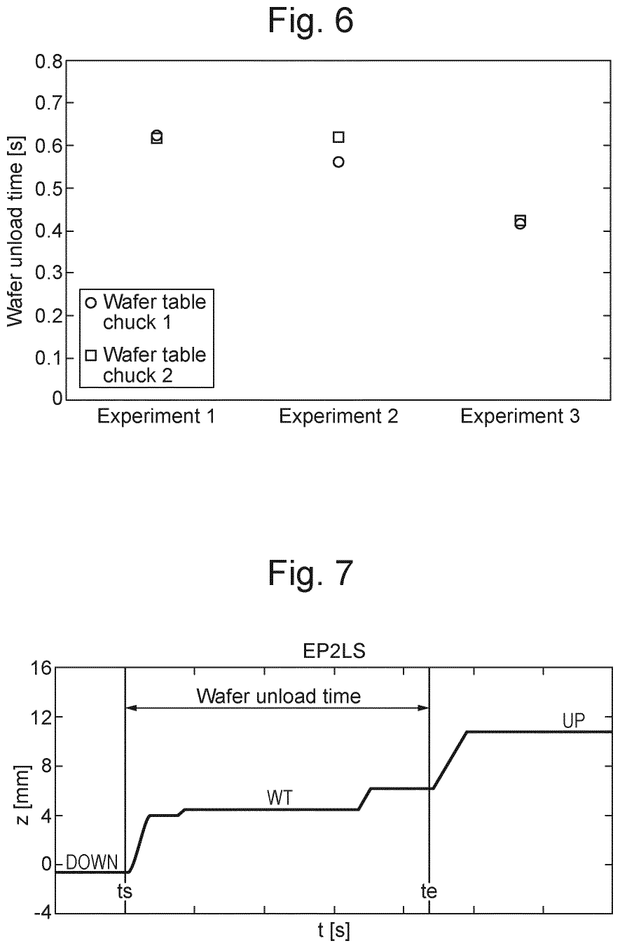

The present inventors have discovered that there is a link between the amount of liquid near the edge of the substrate table WT and the unload time for a substrate W. FIG. 6 shows the substrate unload times for three experiments in each of which two substrates W were unloaded from substrate tables WT (e.g., “wafer table chuck 1” and “wafer table chuck 2”). In Experiment 1, a “normal” arrangement was simulated in which both substrate tables WT were fully wet around their edges and a long unload time of over 0.6 s was recorded. In Experiment 2, a different fluid handling structure IH movement profile over the substrate tables WT was used. The edge of the substrate table WT on wafer table chuck 2 remained fully wet and, again, an unload time of over 0.6 s was recorded. The edge of the substrate table WT on wafer table chuck 1 partly dried out and a shorter unload time of approximately 0.56 s was recorded. For Experiment 3, the fluid handling structure control IH was deliberately adjusted so that no immersion liquid (e.g., UPW) was present. This caused both substrate tables WT to remain fully dry and a faster unload time of slightly over 0.4 s was recorded for both. Thus it can be seen that the unload time for a substrate W which is loaded on even a partially dry substrate table WT is less than the unload time for a substrate W which is loaded on a fully wet substrate table WT.

Thus, the unload time for the substrate W can be used as an indicator of whether the substrate table WT was fully wet or at least partially dry. This approach can have the benefit of being able to immediately identify a potential issue when substrates W are unloaded and, in particular, is considered likely to be more accurate than, for example, measuring substrate alignment residuals which may miss deformations arising from clamping due to under-sampling of the substrate alignment marks, and also will not generally allow distinction to be made between different potential causes for the alignment residuals. Substrate alignment residuals also cannot be used to detect issues in zero-combined layers since no substrate alignment is performed in such layers and the alignment markers have not yet been formed.

In embodiments, the unload time for a substrate W can be measured accurately by a measurement system 500 using the movement of a movable part relative to the support body 30 of the substrate table WT. In an embodiment, e-pins 38 are used to lift the substrate W from the surface of the substrate table WT and can thus form the movable part. The movement of the e-pins 38 in lithographic apparatus is already highly controlled and measured and so provides a highly reliable indicator of the substrate unload time. As the movement of the e-pins 38 is already measured, no additional physical components or sensors need to be added to existing lithographic apparatus in order to measure the substrate unload times in this manner.

FIG. 7 shows the relatively height z (y axis) of an e-pin 38 during substrate unload. The substrate unload time can be measured as being the time from the start (te) of upward movement of the e-pins 38 from a retracted position in which they are below the support plane P, to the time (ts) at which the e-pins 38 reach an extended position in which the top end of the e-pins 38 is a predetermined height, either from the retracted position, or above the support place P, and the substrate W is supported above and out of contact with the projections 32 and outer projections 32a. The predetermined height in the example of FIG. 7 is 6 mm.

In an alternative embodiment, the substrate W is unloaded from the substrate table WT by a different mechanism such as a gripper (not shown in figures) which engages with the side and/or top of the substrate W, or a vortex gripper. In such arrangements, the time taken to unload each substrate W using this different mechanism could be similarly determined by measuring the movement and/or position of this mechanism.

Substrate unload times could alternatively or additionally be derived from signals from other sensors used in lithographic apparatus. Examples of these are pressure sensors and/or thermal sensors.

Dedicated additional sensors could alternatively or additionally be provided to measure the substrate unload times, but these may be difficult to implement on existing systems.

The substrate unload times, determined by any of the above approaches, or by further alternative approaches, can be compared with a reference time which has been determined to be useful to distinguish between wet and dry substrate tables WT during unload. For example, in the apparatus tested in the experiments shown in FIG. 6, 0.6 s may be chosen as the reference time. When a substrate unload time is measured or calculated which is less than the reference time by more than a predetermined amount, an alert signal can be generated.

The exact choice of reference time and the predetermined amount will depend on one or more of: the lithographic apparatus, the substrates W, the unloading mechanism, and the desired accuracy and tolerances as well as other factors. It will be appreciated that choosing a reference time and/or predetermined amount which causes an alert signal to be generated for even small variations from the observed or predicted normal unload times may result in a higher proportion of false positive results. Conversely, choosing a reference time and/or predetermined amount which is too far removed from the observed or predicted normal unload times may result in a low detection rate of potentially deformed substrates W.

The present inventors have also determined that monitoring of the clamping pressure (the underpressure below the substrate W which holds it onto the substrate table WT during a lithographic process) can be used to detect potentially deformed substrates W.

It has been found that the local drying and resulting friction variation of the outer projections 32a can be particularly important for substrate tables WT in which changes in the water management between the inner, i.e., first, and outer, i.e. second, seal 34, 36 and/or changes in the clamping pressure design can significantly speed up drying times. Even during normal operation and without long delays, local effects can become visible in the alignment/overlay of the substrates W.

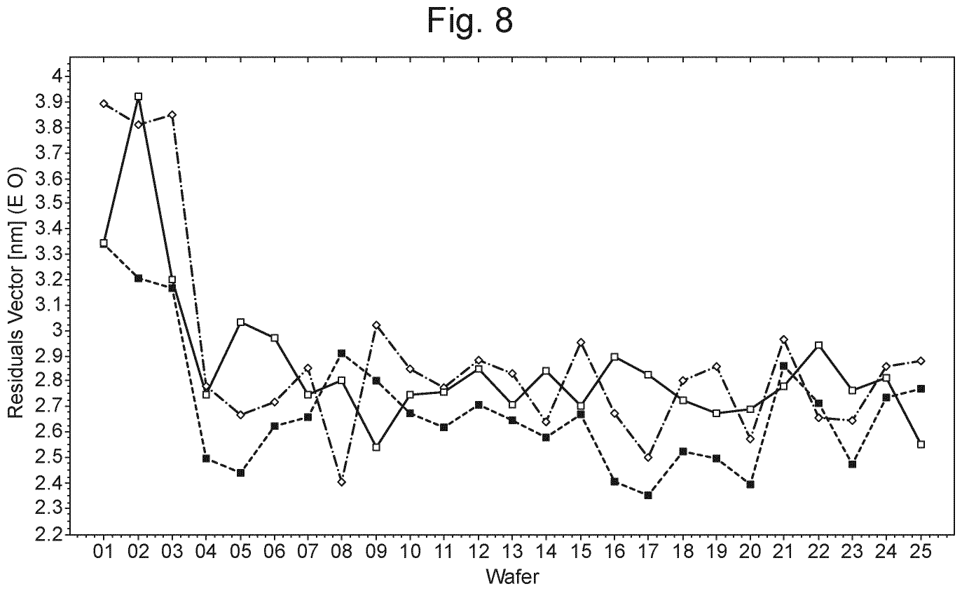

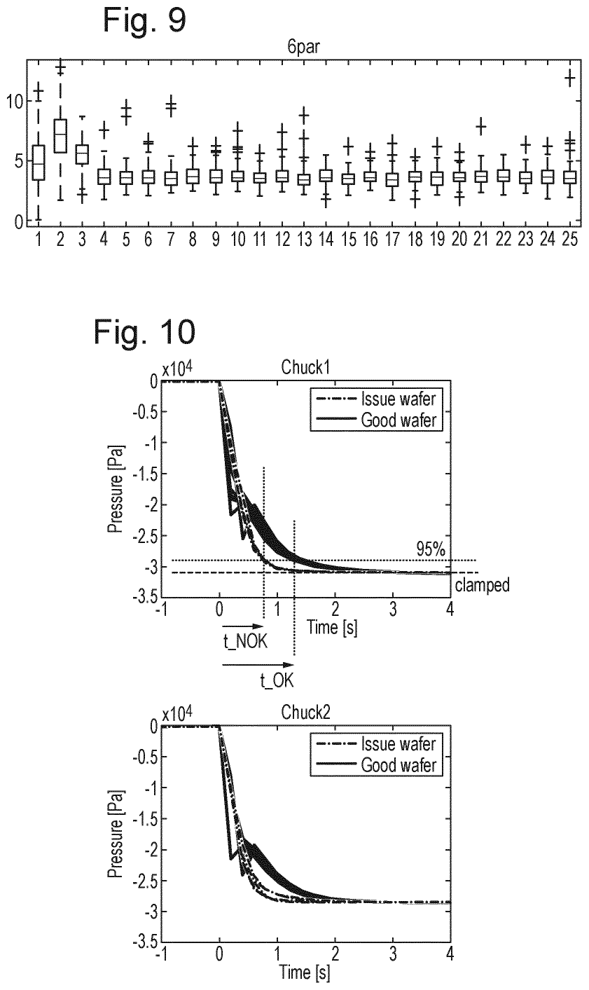

FIGS. 8 and 9 show example performance from a series of tests on initial substrates on a substrate table WT. In FIGS. 8 and 9 the changes in the observed positions of markers from their expected positions is plotted on the y-axis for the substrates at each of the sequentially positions indicated on the x-axis. In FIG. 8, the alignment performance of three lots is shown. FIG. 9 shows the average alignment performance of initial substrates from a plurality of lots. The crosses show the individual readings, the horizontal line the mean and the box shows the three sigma variation of the readings.

It can be seen from both FIGS. 8 and 9 that there is clear performance degradation for substrates in positions 1-3 within a lot. It is believed that extra actions required for start-up lots, such as the handling of closing substrates, can introduce approximately a few seconds of timing delays, resulting in the overlay effects. For example, it was observed that a delay of approximately 6 seconds occurred prior to the loading of substrate 3, which still led to performance degradation.

The substrate table WT pre-clamping pressure build for several lots were analysed and compared to later lots during production lithographic processes. FIG. 10 shows the recorded pre-clamp pressure profiles (i.e. the change in underpressure prior to clamping at an underpressure of approximately 3.1 Pa) over time for the substrates W which were found to suffer from alignment issues and the rest of the substrates (which did not). Substrates 1 and 3 of each lot are loaded on chuck 2 (right hand graph in FIG. 10), whilst substrate 2 from each lot are loaded on chuck 1 (left hand graph in FIG. 10). The three lots for which the pressure profiles were analysed in FIG. 10 are the same three lots whose alignment errors are shown in FIG. 8.

From the recorded pressure profiles shown in FIG. 10 it can be seen that the substrates W which had alignment issues showed a different pressure profile in the build up to clamping pressure.

Thus, in further embodiments, measurement of the clamping pressure or clamping pressure change is used to determine whether a substrate W may have suffered deformation due to clamping.

In a first such embodiment, a cut-off time value for clamping pressure build-up is measured. This is defined as the time taken for the clamping pressure to reach 95% of the final clamped pressure, which is indicated by the “95%” dotted line in FIG. 10. As can be seen from FIG. 10, the substrates with alignment issues reach the 95% value quicker than the normal substrates and so the measured cut-off time can be compared to a reference threshold in order to determine whether the substrate W may have suffered deformation due to clamping. In the example shown in FIG. 10, this threshold could be, for example, 1 second.

It will be appreciated that alternative definitions of the cut-off time could be used. From the recorded pressure profiles shown in FIG. 10, it can be seen that the profiles deviate between approximately 70% of final clamped pressure and 100% of final clamped pressure, although the deviation is more substantial between around 85%-100% of final clamped pressure.

The appropriate choice of reference threshold value for the cut-off time is likely to need to be determined empirically for different types of lithographic apparatus (and possibly also for different substrates W), and will also be dependent on the definition of the cut-off time.

In a second such embodiment, pressure build up profiles of known good and problematic substrates W can be determined empirically for particular combinations of lithographic apparatus and substrates W and stored as reference profiles. These stored reference profiles can be compared to measured profiles during operation of the lithographic apparatus and a determination made depending on whether the measured profile is a better fit with the stored profile for the problematic substrates or the good substrates.

Having determined that a substrate W may have suffered deformation due to clamping (for example because a substrate unload time was measured to be a defined proportion less than the expected unload time or the clamping pressure deviated from the expected profile), a substrate reject strategy may be implemented which prevents such substrates W from being further used in the lithographic process. The specific thresholds for rejection can be set on a user-by-user basis and may be chosen depending on the desired accuracy and/or characteristics of the substrates W and/or the lithographic apparatus.

Alternatively or additionally a system re-wetting process may be initiated to ensure that the substrate table WT is fully wet for future substrate loads and unloads. This may involve reloading the substrate W which has been determined as suffering deformation, or an alternative substrate. The alternative substrate may be a closing substrate or a dummy substrate which is already used in many lithographic apparatuses in order to, for example, to protect the substrate table WT when the system is idle, or in other functions when no production substrates W are present. Once such substrate is re-loaded the standard exposure process can be run (including wetting of the substrate table WT) and then that substrate is unloaded and subsequent substrates W may be loaded as normal for exposure to patterning radiation.

Alternatively or additionally the apparatus may be arranged to use a different alignment approach from the standard approach with any substrate W identified as potentially having suffered deformation. This may include a change in alignment strategy or measuring with an extended layout of markers to better capture the overlay/alignment fingerprint. It may also include changing one or more parameters or settings in the alignment process.

As will be appreciated, any of the above described features can be used with any other feature and it is not only those combinations explicitly described which are covered in this application.

Although specific reference may be made in this text to the use of lithographic apparatus in the manufacture of ICs, it should be understood that the lithographic apparatus described herein may have other applications in manufacturing components with microscale, or even nanoscale, features, such as the manufacture of integrated optical systems, guidance and detection patterns for magnetic domain memories, flat-panel displays, liquid-crystal displays (LCDs), thin-film magnetic heads, etc.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus, it will be apparent to one skilled in the art that modifications may be made to the invention as described without departing from the scope of the claims set out below.

1. A substrate support system, comprising:
a support part, the support part configured to support a bottom surface of a substrate on a support plane;
a moveable part, the moveable part moveable between a retracted position, in which a top end of the moveable part is below the support plane, and an extended position, in which the top end of the moveable part is above the support plane, such that the top end contacts the bottom surface of a substrate supported by the support part when moving between the retracted and extended positions and supports the bottom surface of the substrate above the support plane in the extended position; and
a measurement system configured to measure a time taken for the moveable part to move from the retracted position to the extended position, to compare the measured time with a reference time, and to generate a signal when the measured time deviates from the reference time by more than a predetermined amount.

2. The substrate support system according to claim 1, wherein the support part comprises a support body and the movable part comprises a plurality of pins which are movable through the support body.

3. The substrate support system according to claim 2, wherein the support part has a plurality of first projections extending from the support body forming the support plane and arranged to support the bottom surface of the substrate.

4. The substrate support system according to claim 3, further comprising a first seal member extending from the support body at an edge region of the support part, the first seal member surrounding the plurality of first projections, and a second seal member extending from the support body at the edge region of the support part, the second seal member surrounding the first seal member.

5. The substrate support system according to claim 4, further comprising a plurality of second projections extending from the support body and arranged between the first seal member and the second seal member, the plurality of second projections configured to support the substrate on the support plane.

6. The substrate support system of claim 4, further comprising a plurality of extraction openings formed in the support body for the extraction of fluid from between the support part and the substrate.

7. The substrate support system of claim 6, wherein the plurality of extraction openings are arranged between the first seal member and the second seal member.

8. A stage positioning system comprising:
a substrate support system arranged to support a substrate;
a clamping system arranged to hold the substrate on the substrate support whilst the substrate is being exposed to radiation;
a processor; and either:
a) a sensor arranged to measure a time taken for a substrate to be removed from the substrate support, wherein the processor is arranged to compare the time measured by the sensor to a reference time, and to generate a signal when the measured time deviates from the reference time by more than a predetermined amount, or
b) a sensor arranged to measure a change in a pressure used by the clamping system to clamp the substrate to the substrate support, wherein the processor is arranged to compare the measured pressure change to a reference, and to generate a signal based on the comparison.

9. The stage positioning system according to claim 8, comprising the sensor arranged to measure a time taken, wherein the processor is arranged to compare the time measured, wherein the clamping system is arranged to hold the substrate in a support plane, and wherein the sensor is arranged to measure the time taken for the substrate to be moved from the support plane to a position separated from the support plane.

10. (canceled)

11. The stage positioning system according to claim 8, comprising the sensor arranged to measure a time taken and wherein the sensor arranged to measure a time taken is a pressure sensor or a thermal sensor.

12. The stage positioning system according to claim 8, comprising the sensor to measure a change in a pressure, wherein the processor is arranged to compared the measured pressure change and wherein the processor is further arranged to:
measure the time taken for the measured pressure change to reach a predetermined pressure threshold;
compare the measured time taken to a predetermined time threshold; and
generate the signal if the measured time is either below or above the time threshold.

13. The stage positioning system according to claim 8, comprising the sensor to measure a change in a pressure, wherein the processor is arranged to compare the measure pressure change and wherein the processor is further arranged to:
record the change in pressure with time to generate a pressure profile;
compare the recorded pressure profile to a stored profile of a pressure change; and
generate the signal either if the recorded pressure profile matches the stored profile or if the recorded profile does not match the stored profile.

14. The stage positioning system according to claim 8, wherein the stage positioning system is further arranged to, if the signal is generated, remove the substrate from the stage positioning system.

15. A lithographic apparatus comprising the stage positioning system according to claim 8.

16. The stage positioning system according to claim 8, comprising the sensor arranged to measure a time taken for a substrate to be removed from the substrate support, and wherein the processor is arranged to compare the time measured by the sensor to a reference time, and to generate a signal when the measured time deviates from the reference time by more than a predetermined amount.

17. The stage positioning system according to claim 8, comprising the sensor arranged to measure a change in a pressure used by the clamping system to clamp the substrate to the substrate support, and wherein the processor is arranged to compare the measured pressure change to a reference, and to generate a signal based on the comparison.

18. A method of exposing a substrate in a lithographic process, the method comprising:
clamping the substrate to a support structure;
exposing the clamped substrate to radiation; and
removing the substrate from the support structure,
either:
a) measuring a time taken to remove the substrate from the support structure, comparing the measured time to a predetermined reference time, and responsive to the measured time deviating from the reference time by more than a predetermined amount, generating a signal, or
b) measuring a change in a pressure used to clamp the substrate to the support structure during the clamping, comparing the measured pressure change to a predetermined reference, and based on the comparison, generating a signal.

19. The method according to claim 18, comprising the measuring the time taken and wherein the measuring the time taken measures the time taken for a release mechanism to move from a first position in which the mechanism is not contacting the substrate to a second position in which the mechanism is contacting the substrate and holding the substrate in a position removed from the support structure.

20. The method according to claim 18, comprising the measuring a change in pressure, wherein the measuring the change in pressure further comprises measuring the time taken for the measured pressure change to reach a predetermined pressure threshold, wherein the comparing compares the measured time taken to a predetermined time threshold; and wherein the signal is generated if the measured time is either below or above the time threshold.

21. The method according to claim 18, comprising the measuring a change in pressure, wherein the measuring the change in pressure further comprises recording the change in pressure with time during the clamping to generate a pressure profile, wherein the comparing compares the recorded pressure profile to a stored profile of a pressure change, and wherein the signal is generated either if the recorded pressure profile matches the stored profile or if the recorded profile does not match the stored profile.

22. The method according to claim 18, further comprising detecting whether the signal is generated and, if the signal is generated, removing the substrate from the lithographic process.

23. A computer program product comprising a non-transitory computer-readable medium having computer-readable instructions therein, which instructions, when run on suitable computer apparatus, cause the computer apparatus to at least perform the method of claim 18.
